(19) United States
(12) Patent Application Publication
(10) Pub. No.: US 2002/0093106 A1
(43) Pub. Date: Jul. 18, 2002

(54) Bonding pad for flip-chip fabrication

(76) Inventors: Ashok Krishnamoorthy, City of Middletown, NJ (US); Keith W. Goossen, City of Howell, NJ (US)

Correspondence Address: Keith Goossen, 137 Easy Street, Howell, NJ, 07731, US

(21) Appl. No.: 09/761,886

(22) Filed: Jan. 17, 2001

(51) Int. Cl. H01L 21/44; H01L 21/48; H01L 21/50; H01L 23/48; H01L 23/52; H01L 29/40

(52) U.S. Cl. 257/778; 438/108

(57) ABSTRACT

A flip-chip bonding system. In flip chip bonding, a planar array of metallic pads is bonded to a mirror-image array by a film of solder between each pad-pair. Prior to bonding, testing may be done, by applying a mechanical probe to the pads, and reading, or applying, electrical signals. The probe may damage very small pads. Under the invention, small pads are configured in two parts, connected together. One part is used for probing, and the other is used to make the solder connection.

The invention relates to integrated circuits in flip-chip systems, and to bonding pads for such systems. In such systems, a very high packing density of pads is desired, to attain high miniaturization. However, a high packing density implies small pads, which implies structurally weak pads. Weak pads can be damaged by mechanical probes used to electrically test the integrated circuits, prior to bonding. The invention reduces, or eliminates, the damage problem.

### BACKGROUND OF THE INVENTION

“Flip chip” bonding is utilized when integrated circuits must be connected to each other, but when the integrated circuits are fabricated using different material systems.

For example, an array of lasers may transmit optical signals to receivers, and may be controlled by control/driver circuitry. The lasers would typically be fabricated using a gallium-arsenide-type system. However, the control/driver circuitry would most likely be fabricated using a silicon-based system.

If both the lasers and the control/driver circuitry were fabricated in the same material system (ie, both in silicon or both in gallium arsenide) , connection between the two, in principle, would be simple. For example, a layer of aluminum may be deposited, and then etched away, to leave the desired connections remaining.

However, this approach is not possible, or at least not convenient, when one component is fabricated in gallium arsenide, and the other is fabricated in silicon.

One solution to the problem is to use flip-chip bonding. FIG. 1 illustrates a gallium arsenide substrate, GaAs, and a silicon substrate Si. The substrates are also called “dies.” Metallic pads P are shown on each.

In FIG. 2, a film F of solder is deposited on each pad P on one of the substrates, the GaAs in this example. In FIG. 3, the silicon substrate Si is inverted, or flipped, as indicated, and the substrates GaAs and Si are laminated together as in FIG. 4. Upon heating, the solder W fuses, and bonds the pads P together.

In this simplified example, the circuitry connecting to the pads P, and the connections themselves, have not been shown.

The Inventors have observed a problem in this process, when the pads P reach very small sizes.

### SUMMARY OF THE INVENTION

In one form of the invention, the pad used in flip-chip bonding comprises two regions: (1) a larger, body region which is contacted by a probe, for testing, and (2) a smaller, head region, extending from the larger region, which is used exclusively for flip-chip bonding. Any damage which a mechanical probe causes to the larger region does not affect the bonding ability of the smaller region.

### BRIEF DESCRIPTION OF THE DRAWINGS

FIGS. 1-4 schematically illustrate a sequence of steps commonly undertaken in flip-chip bonding, as known in the prior art.

FIG. 5 illustrates a problem which occurs when very small flip-chip pads are probed by a probe PR.

FIG. 6 illustrates one form of the invention.

FIGS. 7, 8, 9, and 10 illustrate different embodiments of the invention.

FIG. 11 is a flow chart illustrating processes undertaken by one form of the invention.

### DETAILED DESCRIPTION OF THE INVENTION

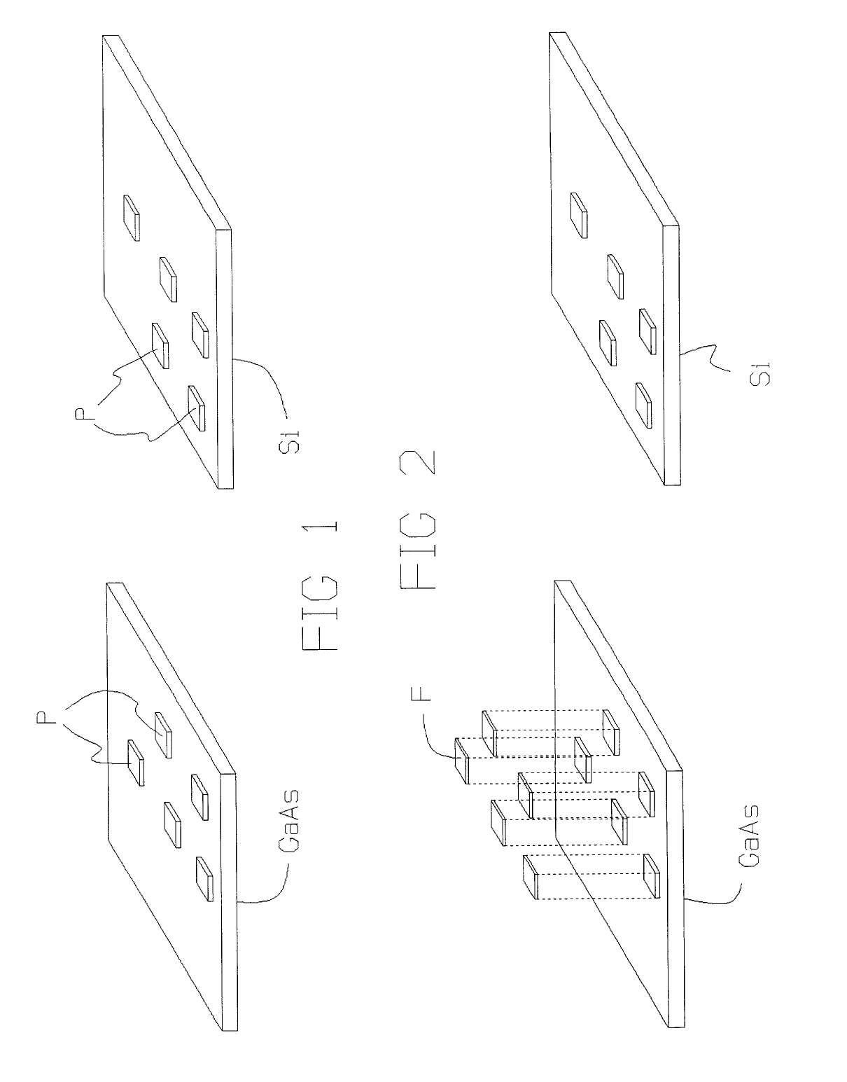

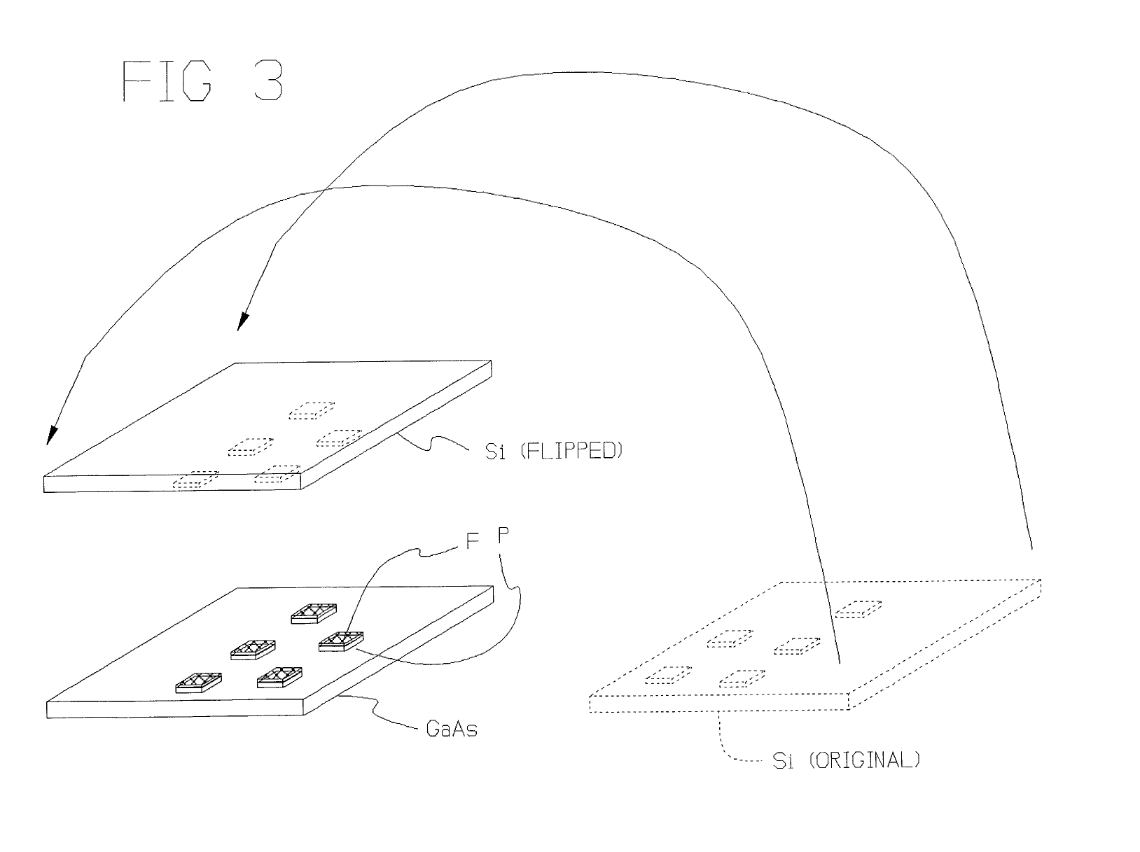

Prior to assembly of the two substrates shown in FIGS. 1-4, they may be tested. In the testing, gangs of probes (not shown) are brought into electrical contact with the pads P. FIG. represents one probe PR contacting a pad P.

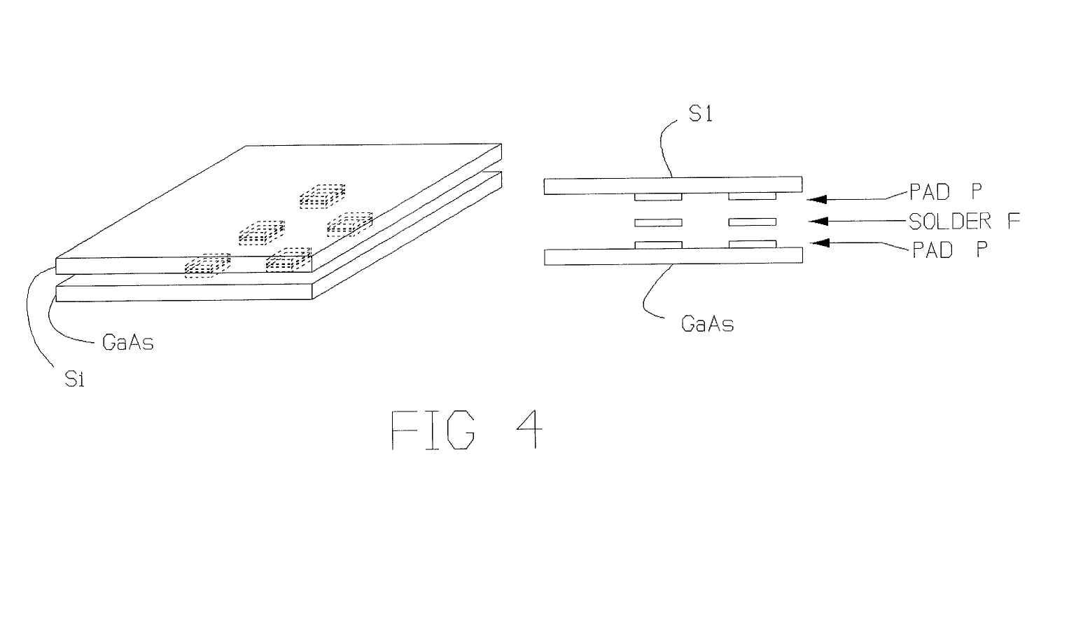

The inventors have observed that, when the pads P attain very small dimensions, the probe PR can damage, or at least alter, the pads P. The damage, or alteration, can cause a defective bond between the solder F and the pads P in FIG. 4.

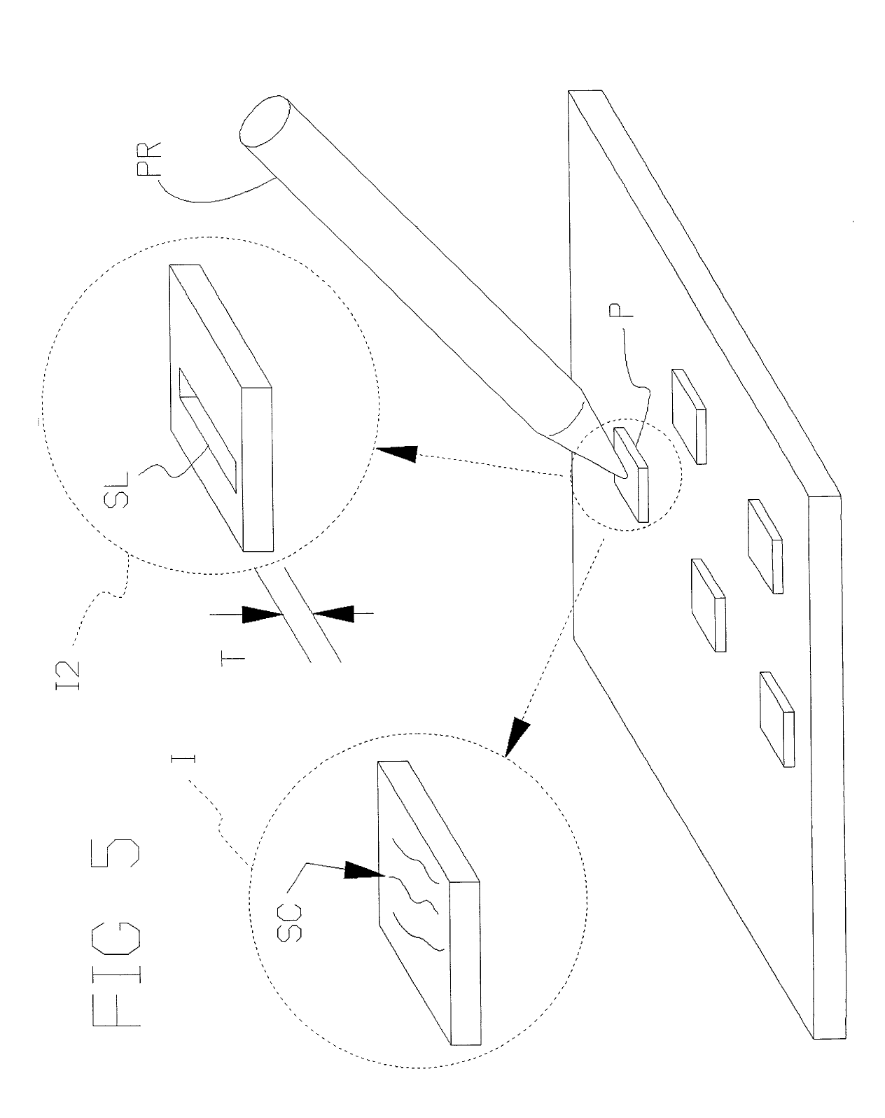

For example, the probe PR in FIG. 5 can generate scratches SC on a pad P, as indicated in insert I. Further, the scratches can become sufficiently deep as to completely penetrate the pad P, as shown in insert I2. The scratches have now become slits SL in the pad P.

One reason the scratching problem arises is that the pads P are extremely thin, in the range of one, or a few, microns in thickness. The reader is reminded that one micron equals one millionth of a meter. 25.7 microns equal one mil, which is one milli-inch, that is, 1/1,000 inch.

As a frame of reference, a human hair is a couple of mils in diameter. If a human hair is assumed to be 4 mils in diameter, or about 100 microns, then 100 thicknesses of pad P in FIG. 5 would equal the diameter of this human hair. Thus, the thickness T of the pads P is one percent of the diameter of this human hair. Consequently, the pads P, being very thin, are fragile.

In addition, the pads P tend to be fabricated of soft alloys, often containing the soft metal gold. These alloys are chosen for their properties of good adhesion to solder alloys. Thus, in addition to being structurally thin, the small pads P are relatively soft. For both these reasons, the pads P are easily damaged.

The damage causes poor solder adhesion, for at least the following two proposed reasons. If the probe PR in FIG. 5 creates a slit SL in a pad P, the slit SL can expose the surface of the silicon substrate. The solder alloy will not bond to silicon. Thus, with the slit present, the only structure now available for bonding by the solder alloy is the remaining frame of the pad P, which surrounds the slit. Surface tension effects create difficulty for the solder alloy to successfully wet the frame.

As to the second reason, in the case of scratches SC in insert I, similar wetting problems are created. At the microscopic scale, the scratches appear as large mountains and valleys. However, the outer surface of the fused solder film tends to assume a smooth shape, much as small quantities of water tend to round themselves into smooth spheres. The solder has difficulty in conforming to the mountains and valleys, and thus does not easily wet those structures.

Stated more technically, the smooth surface of the fused solder represents a thermodynamically preferred state of lowest energy. That is, if the bonds between individual solder atoms are viewed as springs, then the collective stretching of all springs at the surface is reduced when the surface is smooth, as compared to being rough and jagged. Therefore, for the surface of the solder to become conformal to the microscopic mountains and valleys of the scratches SC in the pad P, additional energy must somehow be added to deform that solder surface.

The preceding two explanations are hypotheses proposed by one or more of the Inventors to explain the observed facts, which include the observations that when (1) the pads P are fabricated at a sufficiently small size, and (2) then the pads P are placed into contact with probes which test the associated circuits, difficulties in solder adhesion in subsequent flip-chip bonding are encountered.

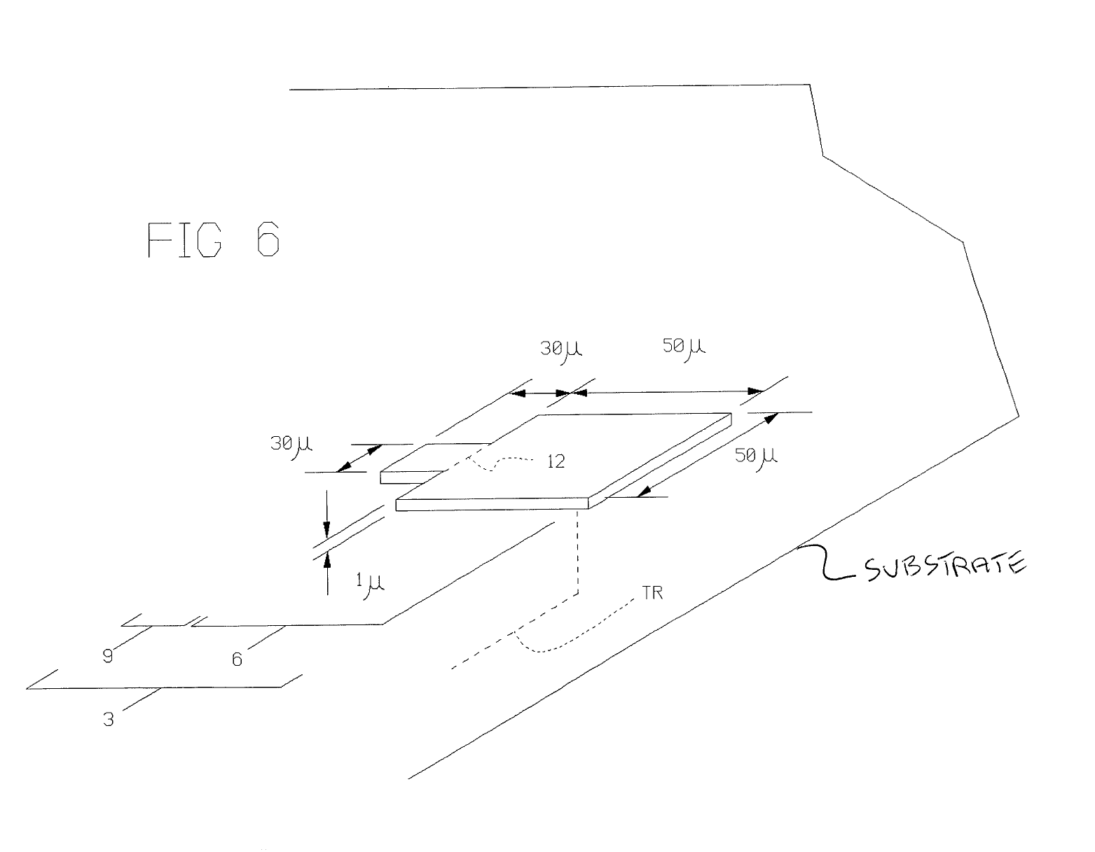

The hypotheses, and other factors, have led the Inventors to investigate the form of the invention as shown in FIG. 6. A two-part pad 3 is shown. One part 6 is used exclusively for probing. A second part 9 is used exclusively for flip-chip bonding. Both parts 6 and 9 are electrically connected together along border 12. The overall pad 3, of course, connects to a trace TR which leads to other components (not shown).

Under this arrangement, damage to probe, or body region 6 has no effect on the solder, or head region 9.

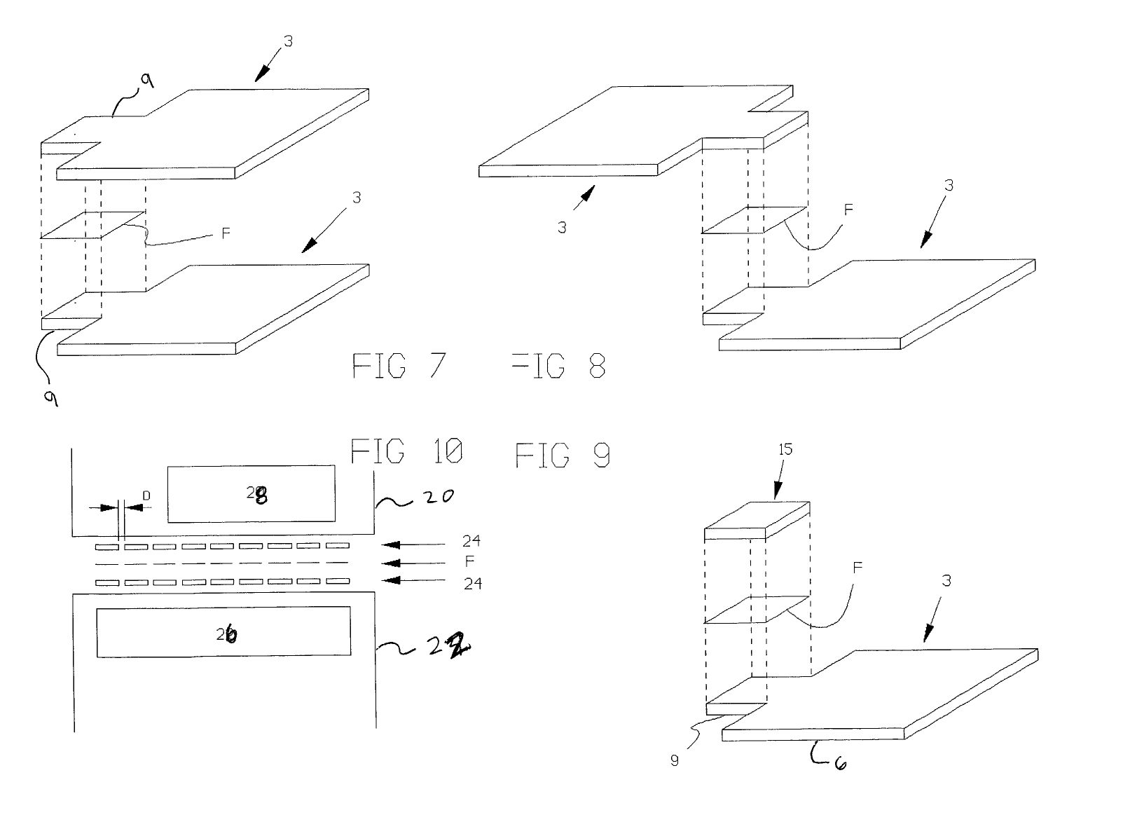

FIG. 7 illustrates, in exploded view, a structure provided by one form of the invention. Two pads 3 are shown, and the solder pads 9 of each are connected together by a film F of solder. The pads are supported by their respective semiconductor substrates, which are not shown.

FIG. 8 illustrates another arrangement, wherein the probe pads 6 are positioned 180 degrees apart. Other relative positionings, from zero degrees to 259 degrees, are possible.

FIG. 9 illustrates another arrangement, wherein a solder pad 15 is connected to a pad according to the invention. Pad 15 may be equal in size to the solder pad 9, or another size.

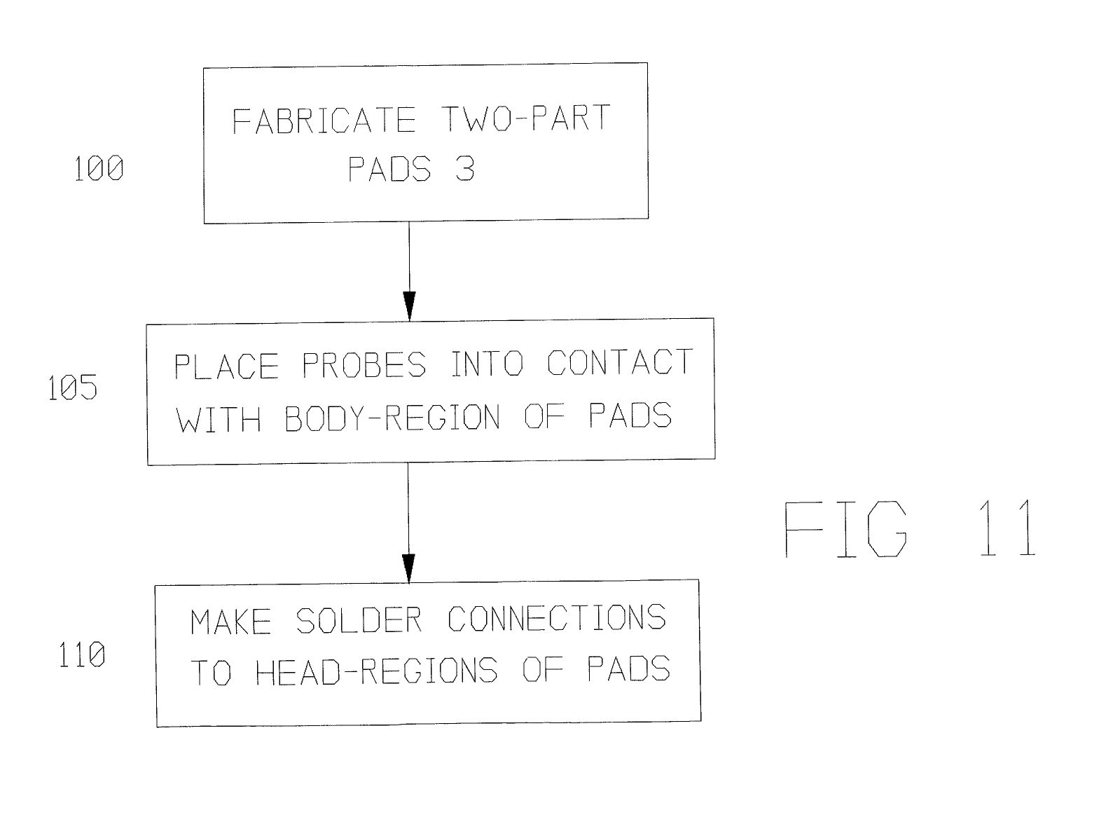

FIG. 10 illustrates an exploded, cross-sectional view of one form of the invention. Substrates 20 and 22, which are of different crystalline materials, such as gallium arsenide and silicon, support pads 24. Each pad 24 represents one of the pads in FIGS. 7-9. Films F of solder are shown in FIG. 10. Adjacent pads 24 are separated by a distance D, which lies in the range of 100-250 microns.

For example, the pads may be arranged in pairs, with each member of the pair separated from the other by 100 microns. However, adjacent pairs may be separated by 250 microns. Conversely, the two pair members may be separated from each other by 250 microns, with adjacent pairs separated by 100 microns.

Preferably, substrate 22 carries an array of light emitters, such as lasers, or an array of photodetectors. Block 26 represents the array. Preferably, substrate 24 carries control/driver circuitry, indicated by block 28.

Further details on the construction of the apparatus of the type represented in FIG. 10, with the exception of the pads of FIG. 6 herein (which are the subject of the present invention), are found in the journal article entitled, “16×16 VCSEL Array Flip-Chip Bonded to CMOS VLSI CIrcuit,” by A. V. Krishnamoorthy, K. W. Goossen, L. M. F. Chirovsky, R. G. Rozier, P. Chandramani, W. S. Hobson, S. P. Hui, J. Loprain, J. A. Walker, and L. A. D'Asaro, and published in IEEE Photonics Technology Letters, Vol. 17, No. 8, August, 2000, p. 1073. This article is hereby incorporated by reference. The pads of the present invention are used in the type of structure described in the article.

FIG. 11 is a flow chart illustrating processes undertaken by one form of the invention. In block 100, pads of the type shown in FIG. 6 are fabricated n semiconductor wafers.

In block 105, the body-part 6 of the panhandle pads are placed into contact with probes, as for testing. In block 110, the head-part 9 of the panhandle pads are used for making solder connections. Significantly, the body-part is not used for making a solder connection, except for incidental migration of solder from the head-part. Also, the head-part is not used for probing, but exclusively for effecting a solder connection.

### Additional Considerations

1. The head 9 in FIG. 9 is connected to another contact, such as pad 15, by a film of solidified solder F. However, the body 6 is not involved in this solder contact.

The head 9 contains an area of 30×30 square microns, or 900 square microns, while the body 6 contains an area of 50×50 square microns, or 2500 square microns, which is 2.7 times larger. Thus, the area wetted by the solder film W is about 1/2.7 the area of that not wetted. From another perspective, the area of the overall pad 3 which is wetted is 900/(900+2500), or about 26 percent.

2. The dimensions of FIG. 6 are taken as nominal. The head 9 can range from a dimension of 5×5 microns to 40×40 microns. The body 6 can range from 40×40 microns to 100×100 microns.

Both head and body are preferably the same thickness, and probably will be, for convenience in fabrication. However, identical thicknesses are not required. The thickness can range from 0.2 microns to 2.0 microns.

Any combinations of the preceding dimensions can be used.

3. The Inventors point out that the pad 3 of FIG. 6 contains eight sides (ignoring the top and bottom sides). Those eight sides are either (1) 50 microns, (2) 30 microns, or (3) 10 microns in length. The polygon formed by those sides determines the boundary of the pad 3: the pad does not extend beyond that boundary.

4. The pad 3 may be constructed so that the head 9 in FIG. 6 may be located in a different position. For example, the head 9 may be moved so that its lower right corner coincides with the lower left corner of the body 6. This would produce a somewhat L-shaped structure.

Numerous substitutions and modifications can be undertaken without departing from the true spirit and scope of the invention. What is desired to be secured by Letters Patent is the invention defined in the following claims.

1. An apparatus, comprising:
a) a two-part pad, comprising
i) a first pad, which is rectangular, metallic, about 50 microns×50 microns, and about 1 micron thick; and
ii) a second pad, which is rectangular, metallic, about 30×30 microns, about 1 micron thick, and having one edge coinciding with part of an edge of the first pad; and
c) a semiconductor substrate supporting the two-part pad.

2. Apparatus according to claim 1, wherein damage occurring to the first pad does not inhibit wetting of solder to the second pad.

3. Apparatus according to claim 1, and further comprising electronic circuitry supported by the semiconductor substrate, and a trace connecting to the two-part pad.

4. Apparatus according to claim 3, wherein damage occurring to the first pad as a result of testing of the electronic circuitry does not inhibit wetting of solder to the second pad.

5. A method, comprising:
a) on a semiconductor substrate, constructing a pad which connects to a trace, the pad containing
i) a body, and
ii) a head electrically connected to the body;
b) communicating with the trace by applying a probe to the body; and
c) connecting an external component to the trace by flip-chip bonding to the head.

6. Method according to claim 5, wherein the probe is not applied to the head.

7. Method according to claim 5, wherein the flip-chip bonding does not involve the body.

8. Method according to claim 5, wherein the probe is not applied to the head, and the flip-chip bonding does not involve the body.

9. An apparatus, comprising:
a) a die containing one, or more, integrated circuits;
b) on a surface of the die, a metallic pad having
i) a first region bearing a fused material which connects to a second pad; and
ii) a second region lacking fused material.

10. Apparatus according to claim 9, wherein the first region has an area less than 1600 square microns, and the second region has an area greater than 1600 square microns.

11. Apparatus according to claim 9, wherein the first and second regions are generally rectangular in shape, and share a common border.

12. Apparatus according to claim 9, wherein the die comprises crystalline silicon, the integrated circuit comprises a driver for lasers, and further comprising:
c) a second die, containing
i) lasers, and
ii) a pad connecting to said fused material.

13. Apparatus, comprising:
a) a first array of metallic pads A, supported by a first substrate;
b) a second array of metallic pads B, supported by a second substrate, each pad B connected to a respective pad A by a solder bond;
c) a third array of metallic pads C, each pad C supported by the first substrate and electrically connected to a respective pad A;
d) a control circuit which delivers signals to the pads A; and
e) an array of optoelectronic devices, each connected to a respective pad B.

14. Apparatus according to claim 13, and further comprising
f) a fourth array of metallic pads D, each pad D supported by the second substrate and electrically connected to a respective pad B.

15. Apparatus according to claim 13, wherein each pad B is about 30×30 microns, and 1 micron thick.

16. Apparatus according to claim 13, wherein each pad C is about 30×30 microns, and 1 micron thick.

17. Apparatus according to claim 16, wherein each pad C is separated from its neighbor by about 100 microns.
